(19) United States
(12) Patent Application Publication
(10) Pub. No.: US 2024/0164060 A1
(43) Pub. Date: May 16, 2024

(54) CONNECTION DEVICE

(71) Applicant: INNOLIGHT TECHNOLOGY (SUZHOU) LTD., Jiangsu (CN)

(72) Inventor: Chao ZHANG, Jiangsu (CN)

(73) Assignee: INNOLIGHT TECHNOLOGY (SUZHOU) LTD., Jiangsu (CN)

(21) Appl. No.: 18/284,534

(22) PCT Filed: Dec. 6, 2021
(86) PCT No.: PCT/CN2021/135607

§ 371 Date: Sep. 28, 2023

(30) Foreign Application Priority Data
May 7, 2021 (CN) 202110495499.8

(51) Int. Cl. H05K 7/20

(52) U.S. Cl. CPC H05K 7/2039

(57) ABSTRACT

The present application discloses a connection device, comprising a housing and a heat dissipation block. The housing is provided with an accommodation cavity for insertion of a plug connector, and a heat dissipation Window in communication with the accommodation cavity. The heat dissipationblock is disposed on the side of the housing provided with the heat dissipation Window. The connection device further comprises an adjustment assembly for adjusting the heat dissipation block so as to make the heat dissipation block close to or distant from the accommodation cavity. The heat dissipation block has a thermally conductive connection state in which the heat dissipation block approaches to abut against the plug connector after the plug connector is inserted in place.

### TECHNICAL FIELD

The present disclosure relates to the field of connection devices, in particular to a connection device.

### DESCRIPTION OF RELATED ART

Regarding the connection device for plug-in connection of optical modules and other plug connectors, it includes a housing and a heat dissipation block (i.e. heat sink) fixedly arranged on the housing, in which the housing includes an accommodation cavity for plug connectors to be inserted or pulled out, and the heat dissipation block is used for dissipating heat from the plug connector inserted into the accommodation cavity. In the prior art, the heat dissipation block is usually fixedly arranged on one side of the accommodation cavity. In order to ensure that the heat dissipation block can effectively dissipate heat, when the plug connector is inserted in place in the accommodation cavity, the plug connector needs to abut against the heat dissipation block to form a heat conduction connection with the heat dissipation block. However, based on the prior art, when the plug connector is inserted into the accommodation cavity or pulled out from the accommodation cavity, a sliding friction will be formed between the surface of the plug connector and the heat dissipation block, and the sliding friction will cause damage to the contacting surface of the plug connector and the heat dissipation block.

### SUMMARY

### Technical Problem

The disclosure provides a connection device with a heat dissipation block, which can avoid the problem of damage caused by sliding friction during the plug connector inserting in the connection device in the prior art.

### Technical Solution

An embodiment of the present disclosure provides a connection device, including a housing and a heat dissipation block. The housing is provided with an accommodation cavity for insertion of a plug connector and with a heat dissipation window in communication with the accommodation cavity, and the heat dissipation block is disposed on a side of the housing provided with the heat dissipation window. The connection device further includes an adjustment assembly for adjusting the heat dissipation block so as to make the heat dissipation block close to or distant from the accommodation cavity, and the heat dissipation block includes a thermally conductive connection state in which the heat dissipation block approaches to abut against the plug connector after the plug connector is inserted in place.

In one embodiment, the adjustment assembly includes an inclined guide surface and a guide matching part. The inclined guide surface is located on the heat dissipation block and is disposed away from the housing. The inclined guide surface is inclined toward the housing in an insertion direction of the plug connector, and the guide matching part is fixedly arranged relative to the housing and is slidingly fitted with the inclined guide surface.

In one embodiment, an angle between a plane where the inclined guide surface is located and the insertion direction of the plug connector is 20-45°.

In one embodiment, the heat dissipation block includes a guide hole, and a part of a hole wall of the guide hole facing away from the housing forms the inclined guide surface. The connection device includes a fixed rod fixedly arranged relative to the housing and matched to an inside of the guide hole, and a part of the fixed rod fitted in the guide hole forms the guide matching part.

In one embodiment, the heat dissipation block includes a plurality of fins extending in a same direction as the insertion direction of the plug connector, and the guide hole is located on an outermost fin.

In one embodiment, the adjustment assembly further includes a horizontal guide surface extending in a same direction as the insertion direction of the plug connector, and the horizontal guide surface is connected to an end of the inclined guide surface away from the accommodation cavity.

In one embodiment, the adjustment assembly includes the inclined guide surface and the guide matching part. The inclined guide surface is located on the housing and is disposed away from the heat dissipation block. The inclined guide surface is inclined toward the heat dissipation block in a direction opposite to the insertion direction of the plug connector, and the guide matching part is fixedly arranged relative to the heat dissipation block and is slidingly fitted with the inclined guide surface.

In one embodiment, an angle between a plane where the inclined guide surface is located and the insertion direction of the plug connector is 20-45°.

In one embodiment, the housing includes a guide hole, and a part of a hole wall of the guide hole facing away from the heat dissipation block forms the inclined guide surface. The connection device includes a fixed rod fixedly arranged relative to the heat dissipation block and matched to an inside of the guide hole, and a part of the fixed rod fitted in the guide hole forms the guide matching part.

In one embodiment, the adjustment assembly further includes a horizontal guide surface extending in a same direction as the insertion direction of the plug connector, and the horizontal guide surface is connected to an end of the inclined guide surface away from the heat dissipation block.

In one embodiment, the adjustment assembly further includes a protruding part fixed to the heat dissipation block, and the protruding part protrudes into an inside of the accommodation cavity for abutting against the plug connector to push the heat dissipation block when the plug connector is inserted.

In an embodiment, the connection device further includes an elastic member, and an elastic force of the elastic member enables the heat dissipation block to have a tendency to move away from the housing.

In one embodiment, the plug connector is an optical module.

In one embodiment, the insertion direction of the plug connector is parallel to a plane where the heat dissipation window is located.

### THE BENEFITS OF THE INVENTION

### Benefits

Compared with the prior art, in the technical solution of the present disclosure, the connection device includes an adjustment component that adjusts the heat dissipation block so as to cause the heat dissipation block to be close to or distant from the accommodation cavity. Based on the adjustment component, in the plug-in connection application scenario between the plug connector and the connection device, the heat dissipation block only abuts against the plug connector to form a heat dissipation connection relationship after the plug connector is inserted in place, and before the plug connector is inserted in place and during the pulling-out process, the heat dissipation block is kept separated from the plug connector, thereby avoiding the problem of damage caused by sliding friction during the plug connector inserting in the connection device in the prior art.

### BRIEF DESCRIPTION OF THE DRAWINGS

### Description of the Drawings

FIG. 1 is a schematic diagram of the connection device and the plug connector before assembly according to an embodiment of the present disclosure;

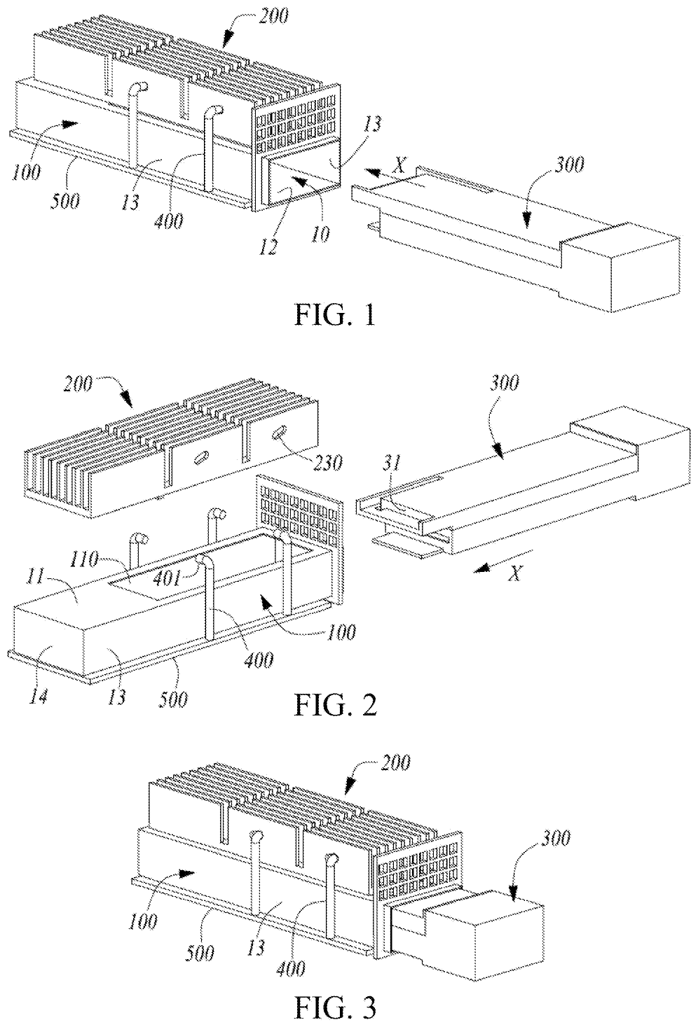

FIG. 2 is a schematic diagram of another angle after disassembly of a housing of the connection device and a heat dissipation block in the structure shown in FIG. 1;

FIG. 3 is a schematic diagram when the connection device shown in FIG. 1 is assembled with a plug connector;

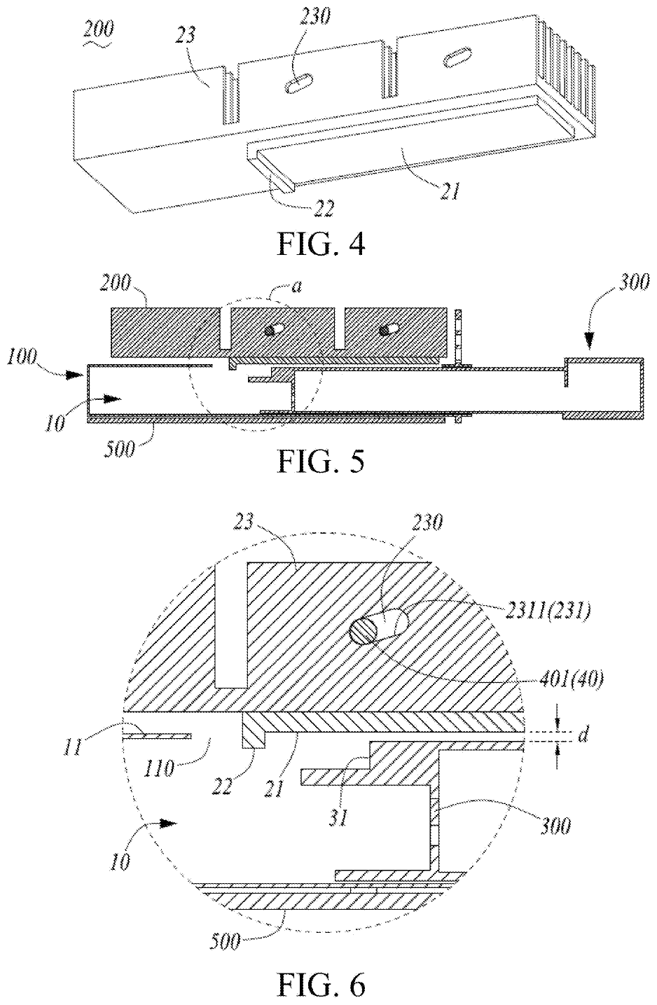

FIG. 4 is a schematic perspective diagram of the heat dissipation block in an embodiment of the present disclosure;

FIG. 5 is a schematic cross-sectional diagram of the plug connector inserted in place in the connection device and cut in the insertion direction;

FIG. 6 is an enlarged schematic diagram of part a in FIG. 5;

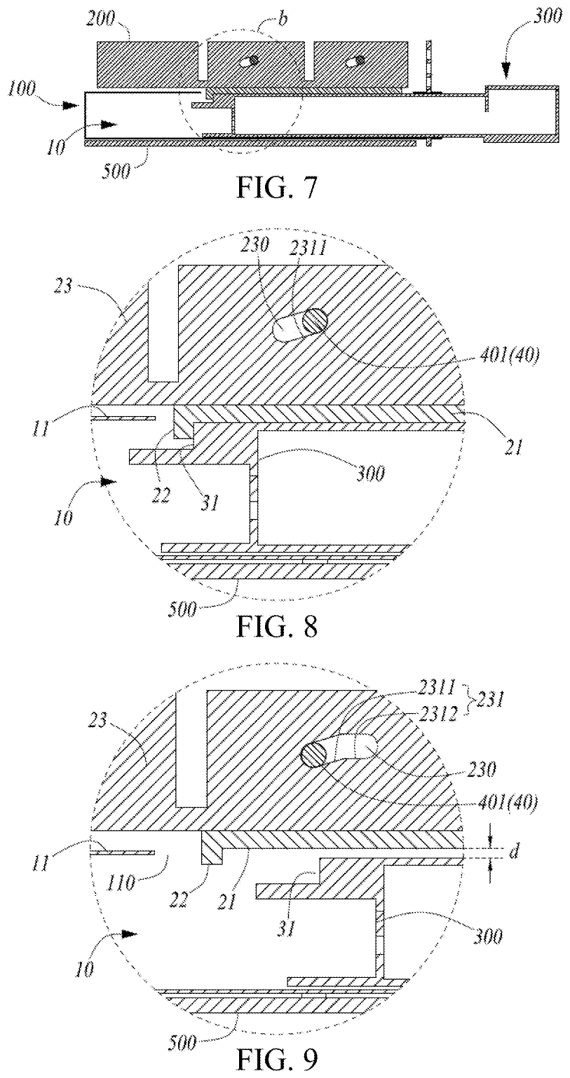

FIG. 7 is a schematic cross-sectional diagram cut along the insertion direction after the plug connector is inserted in place in the connection device;

FIG. 8 is an enlarged schematic diagram of part b in FIG. 7;

FIG. 9 is an enlarged schematic diagram of a partial cross-section of the plug connector before it is inserted in place in another embodiment of the connection device;

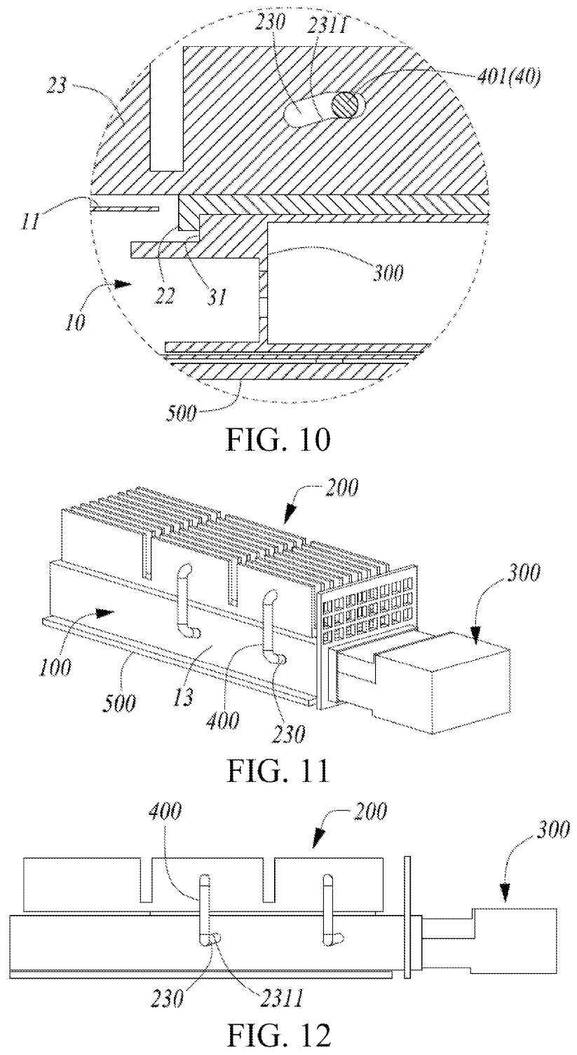

FIG. 10 is an enlarged schematic diagram of a partial section of the embodiment shown in FIG. 9 after the plug connector is inserted in place;

FIG. 11 is a schematic diagram of another embodiment when the structural connection device is assembled with the plug connector; and

FIG. 12 is a schematic side diagram of the structure shown in FIG. 11.

In the figures, 100 is the housing, 10 is an accommodation cavity, 11 is the top wall, 12 is the bottom wall, 13 is the side wall, 14 is the end wall, 110 is the heat dissipation window, 200 is the heat dissipation block, 21 is the heat conduction part, 22 is the protruding part, 23 is the fin, 230 is the guide hole, 231 is the guide surface, 2311 is the inclined guide surface, 2312 is the horizontal guide surface, 300 is the plug connector, 31 is the abutment surface, 400 is the fixed rod, 40 is the guide matching part, 401 is a part where the fixed rod 400 fits in the guide hole 230, and 500 is a fixed plate.

### DESCRIPTION OF THE EMBODIMENTS

### The Embodiments of the Invention

The present disclosure will be described in detail below in conjunction with specific implementations shown in the accompanying drawings. However, these implementations do not limit the present disclosure, and any structural, method, or functional changes made by those skilled in the art based on these implementations are included in the protection scope of the present disclosure.

Reference is made to FIG. 1 to FIG. 3. A connection device associated with the present disclosure includes a housing 100 and a heat dissipation block 200. The housing 100 includes an accommodation cavity 10 for inserting a plug connector 300, and a heat dissipation window 110 communicating with the accommodation cavity 10. The heat dissipation block 200 is disposed on a side of the housing 100 provided with the heat dissipation window 110.

In the embodiment shown in FIG. 1 to FIG. 3, the housing 100 includes a top wall 11, a bottom wall 12, a pair of side walls 13, and an end wall 14 that jointly surround and form the accommodation cavity 10. In the orientation shown in the figures, the top wall 11 and the bottom wall 12 are vertically opposite to each other, the pair of side walls 13 are arranged opposite to each other, and the end wall 14 seals an end of the space formed by the top wall 11, the bottom wall 12 and the pair of side walls 13. The housing 100 further includes an insertion port (not shown in the figures) opposite to the end wall 14, and the plug connector 300 is inserted into the accommodation cavity 10 through the insertion port.

In this embodiment, the heat dissipation window 110 is formed on the top wall 11, and the plug connector 300 inserted into the accommodation cavity 10 is in contact with the heat dissipation block 200 through the heat dissipation window 110, such as to implement the outward dissipation of heat and avoiding overheating of the plug connector 300 during operation.

In a specific embodiment of the present disclosure, the associated plug connector 300 is an optical module. When the plug connector 300 is an optical module, the connection device is provided with an electrical connector electrically connected to the optical module, and the electrical connector and the optical module are jointly inserted to implement the electrical connection. In a specific implementation process, a plurality of connection devices can be electrically connected and fixed on a circuit board.

It should be understood that in other embodiments of the present disclosure, the plug connector 300 may also be other components that need to be inserted and fitted to achieve corresponding functions, and details thereof will not be further expanded here.

In order to better understand the present disclosure, the structural designs associated in the following texts of the present disclosure are all implemented based on the structures described above. However, it should be understood that, in other embodiments of the present disclosure, the heat dissipation window 110 is not limited to being formed on the top wall 11, and may also be formed on the bottom wall 12 or the side wall 13. The housing 100 may not include the end wall 14.

In the present disclosure, the connection device associated further includes an adjustment component for adjusting the heat dissipation block 200 so as to make the heat dissipation block 200 close to or distant from the accommodation cavity 10. The heat dissipating block 200 includes a heat conduction connection state that closes in to abut against the plug connector 300 after the plug connector 300 is inserted in place.

It should be understood that, in the present disclosure, the insertion of the plug connector 300 in place means that the plug connector 300 and the connection device have completed the insertion and cooperation action. Specifically, in the application scenario where the optical module is inserted into the connection device, the insertion in place means that the connection interface on the optical module forms a reliable docking with the corresponding interface in the connection device.

Based on the setting of the adjustment component in the present disclosure, in the application scenario where the plug connector 300 is mated with the connection device, the heat dissipation block 200 can be made to abut against the plug connector 300 to form a thermally conductive connection only after the plug connector 300 is fully inserted in place. Before the plug connector 300 is inserted in place and during the process of the plug connector 300 is pulled out, the adjustment assembly can make the heat dissipation block 200 distant from the accommodation cavity 10 to separate from the plug connector 300, thereby avoiding the problem of damage caused by sliding friction during the insertion and removal of the plug connector 300 in the connection device in the prior art.

In certain embodiments of the present disclosure, the adjustment assembly includes a guide surface 231 and a guide matching part 40. For more detailed structures, reference is made to the following specification.

Reference is made to FIG. 4, FIG. 5, FIG. 6, FIG. 7 and FIG. 8. The guide surface 231 in this embodiment includes an inclined guide surface 2311. The inclined guide surface 231 is located on the heat dissipation block 200 and is disposed away from the housing 100. In the insertion direction of the plug connector 300, the inclined guide surface 2311 is inclined toward the housing 100. The guide matching part 40 is fixedly arranged relative to the housing 100 and is slidingly matched with the inclined guide surface 2311. It should be understood that the insertion direction of the plug connector 300 in the present disclosure corresponds to the X direction in FIG. 1, and generally, the insertion direction of the plug connector 300 is parallel to a plane where the heat dissipation window 110 is located.

In this embodiment, based on the cooperation between the inclined guide surface 2311 and the guide matching part 40, if the heat dissipation block 200 is moved along the insertion direction of the plug connector 300, the heat dissipation block 200 can be moved closer to the accommodation cavity 10. In this manner, when the plug connector 300 needs to be inserted into the housing 100 of the connection device, the heat dissipation block 200 can be driven to move along the insertion direction of the plug connector 300, so as to make the heat dissipation block 200 close to the accommodation cavity 10, and after the plug connector 300 is fully inserted in place, an abutting relationship (that is, a thermal connection) is formed between the heat dissipation block 200 and the plug connector 300 through the heat dissipation window 110, so as to dissipate heat from the plug connector 300 through the heat dissipation block 200. Reference is made to FIG. 7 and FIG. 8 for the state when the contact relationship is formed between the plug connector 300 and the heat dissipation block 200.

In the specific implementation process, the action of the heat dissipation block 200 approaching the accommodation cavity 10 includes the following two implementation methods. The first implementation method is that after the plug connector 300 is fully inserted in place, the inclined guide surface 2311 cooperates with the guide matching part 40, so as to make the heat dissipation block 200 close to the accommodation cavity 10 until it abuts against the plug connector 300. In this manner, there is no linkage relationship between the heat dissipation block 200 and the plug connector 300. In actual implementation, when the plug connector 300 is fully inserted in place, the heat dissipation block 200 can be pushed by hand or driven by a power supply mechanism such as a cylinder to complete the action of the heat dissipation block 200 approaching the accommodating cavity 10. The second implementation is that during the insertion process of the plug connector 300, the inclined guide surface 2311 cooperates with the guide matching part to make the heat dissipation block 200 to approach the accommodation cavity 10, and the heat dissipation block 200 abuts against the plug connector 300 when the plug connector 300 is fully inserted into place. In this manner, there is a linkage relationship between the heat dissipation block 200 and the plug connector 300 (for more details, reference can be made to the embodiments described later). Based on these two implementations, before the plug connector 300 is inserted in place, the surface damage caused by sliding friction between the plug connector 300 and the connection device can be avoided.

Correspondingly, in this embodiment, based on the cooperation between the inclined guide surface 2311 and the guide matching part 40, if the heat dissipation block 200 is moved along the pull-out direction of the plug connector 300 (that is, the direction opposite to the insertion direction), the heat dissipation block 200 can be away from the accommodation cavity 10 of the housing 100. In this manner, when the plug connector 300 needs to be pulled out from the housing 100 of the connection device, the heat dissipation block 200 can be driven to move along the pulling-out direction of the plug connector 300, so as to make the heat dissipation block 200 distant from the accommodation cavity 10, and then during the process of pulling out the plug connector 300, the heat dissipation block 200 is separated from the plug connector 300, so as to prevent the sliding friction between the heat sink block 200 and the plug connector 300 from causing damage to the surfaces of the heat dissipation block 200 and the plug connector 300.

In certain specific embodiments of the present disclosure, the angle between the plane where the inclined guide surface 2311 is located and the insertion direction of the plug connector 300 is 20-45°. After the plug connector 300 is inserted in place, the plug connector 300 will provide an upward force to the heat dissipation block 200. At this time, because the angle between the plane where the inclined guide surface 2311 is located and the insertion direction of the plug connector 300 is 20-45°, the component force of the upward force on the plane where the inclined guide surface 2311 is located is relatively small, so that the relative displacement between the inclined guide surface 2311 and the guide matching part 40 under the action of the upward force can be avoided, and the possibility of the heat dissipation block 200 moving away from the housing 100 spontaneously after the plug connector 300 is inserted in place is reduced, thereby ensuring that a reliable abutting relationship is formed between the heat dissipation block 200 and the plug connector 300.

In a specific embodiment of the present disclosure, as shown in FIG. 1-FIG. 8, the heat dissipation block 200 in this specific embodiment includes a guide hole 230, and a part of the hole wall of the guide hole 230 facing away from the housing 100 forms the inclined guide surface 2311. The connection device further includes a fixed rod 400 fixedly arranged relative to the housing 100 and matched to the guide hole 230. A part 401 of the fixed rod 400 fitted into the guide hole 230 forms the guide matching part 40.

In this specific embodiment, a plurality of guide holes 230 are symmetrically arranged on the left and right sides of the heat dissipation block 200, and each guide hole 230 is matched with a fixed rod 400. Reference is made to FIG. 2 and FIG. 3. In this specific embodiment, the fixed rod 400 is directly fixed to the side wall 13 of the housing 100. In the present disclosure, the connection device further includes a fixed plate 500 fixed on a lower side of the bottom wall 12 of the housing 100. In certain embodiments, the fixed rod 400 can also be fixed to the fixed plate 500, thereby implementing a fixed arrangement relative to the housing 100. An end of each fixed rod 400 away from the fixed plate 500 is bent and fitted into the corresponding guide hole 230 to form the guide matching part 40.

Based on the cooperation between the guide hole 230 and the fixed rod 400 in this embodiment, the heat dissipation block 200 can be movably connected to the housing 100 through the fixed rod 400, so that when the plug connector 300 is not mated to the connection device, the housing 100 and the heat dissipation block 200 can be prevented from being separated into two completely independent modules, and no additional assembly of the housing 100 and the heat dissipation block 200 is required when the connection device is used.

In one embodiment, as shown in FIG. 1 to FIG. 4, the heat dissipation block 200 includes a plurality of fins 23 extending in a same direction as the insertion direction of the plug connector 300. The guide hole 230 described above is located on an outermost fin 23. As shown in the figures, the outermost left side and the outermost right side of the heat dissipation block 200 each have a fin 23 extending in a same direction as the insertion direction of the plug connector 300, and each of the two outermost fins 23 is arranged with two guide holes 230 along the insertion direction of the plug connector 300. It can be understood that the number of guide holes 230 on each outermost fin 23 may not be limited to two.

In other embodiments of the present disclosure, as shown in FIG. 9 and FIG. 10, the guide surface 231 further includes a horizontal guide surface 2312 of which an extension direction is consistent with the insertion direction of the plug connector 300. The horizontal guide surface 2312 is connected to an end of the inclined guide surface 2311 away from the accommodation cavity 10. Reference is made to FIG. 10, based on this implementation structure, when the heat dissipation block 200 is abutted against the plug connector 300, the guide matching part 40 can fit on the horizontal guide surface 2312 instead of on the inclined guide surface 2311, so that the positional relationship between the heat dissipation block 200 and the housing 100 can be better locked.

Specifically, in the embodiment shown in FIG. 6 and FIG. 8, after the plug connector 300 is inserted in place, the plug connector 300 will provide an upward force to the heat dissipation block 200, and the component force of the upward force on the plane where the inclined guide surface 2311 is located may lead to a certain degree of relative displacement between the inclined guide surface 2311 and the guide matching part 40, that is, even after the plug connector 300 is inserted in place, there is still a possibility that the heat dissipation block 200 will move away from the housing 100 spontaneously. However, in the embodiment shown in FIG. 9 and FIG. 10 of the present disclosure, based on the setting of the horizontal guide surface 2312, after the plug connector 300 is inserted in place, the guide matching part 40 is matched to the horizontal guide surface 2312, and the plug connector 300 provides heat dissipation to the heat dissipation block 200, so that it is possible to completely avoid the spontaneous movement of the heat dissipation block 200 away from the housing 100 after the plug connector 300 is inserted in place.

In addition, it should be understood that the guide surface 231 associated in the present disclosure is not limited to the part of the hole wall of the guide hole 230 mentioned above that faces away from the housing 100, and it can also be provided in other forms. For example, the guide surface 231 can be formed on the surface of the heat dissipation block 200 away from the housing 100, and it does not need to be connected with other surfaces to form the shape of the aforementioned guide hole 230.

Reference is made to FIG. 11 and FIG. 12. In other embodiments of the present disclosure, for the adjustment assembly, the inclined guide surface 2311 associated is located on the housing 100 and is disposed away from the heat dissipation block 200, and is in the direction opposite to the insertion direction of the plug connector 300 (that is, the direction in which the plug connector 300 is pulled out). The inclined guide surface 2311 is inclined toward the heat dissipation block 200, and the guide matching part 40 (not shown in FIG. 11 and FIG. 12) is fixedly arranged relative to the heat dissipation block 200 and is slidingly matched with the inclined guide surface 2311. In this embodiment, a method of cooperation between the inclined guide surface 2311 and the guide matching part 40 can be referred to in the specification of the embodiment shown in FIG. 1, and details are not repeated herein.

In more specific detail of the disclosure process above, the angle between the plane where the inclined guide surface 2311 is located and the insertion direction of the plug connector 300 in this embodiment is 20-45°.

Reference is made to FIG. 11 and FIG. 12. The housing 100 of this embodiment includes a guide hole 230, and the part of the hole wall of the guide hole 230 facing away from the heat dissipation block 200 forms the inclined guide surface 2311. The part of the fixing rod 400 that fits into the guide hole 230 forms the guide matching part 40.

In other embodiments of the present disclosure not shown in the figures, on the basis of the embodiment shown in FIG. 11, the adjustment assembly further includes a horizontal guide surface extending in a same direction as the insertion direction of the plug connector 300, and the horizontal guide surface is connected to an end of the inclined guide surface 2311 away from the heat dissipation block 200.

In the present disclosure, the adjustment component is not limited to the structures shown in the above embodiments, and may also be other component structures capable of driving the heat dissipation block 200 close to or distant from the accommodation cavity 10. The assembly structure forming the adjustment assembly can further include components that can provide active driving force such as motors and cylinders, that is, the action of the heat dissipation block 200 approaching or moving away from the accommodation cavity 10 can be driven by components capable of providing active driving force such as motors and cylinders.

In an embodiment of the present disclosure, as shown in FIG. 4 to FIG. 8, the adjustment assembly further includes a protruding part 22 fixed to the heat dissipation block 200. The protruding part 22 protrudes into an inside of the accommodation cavity 10 for abutting against the plug connector 300 to push the heat dissipation block 200 when the plug connector 300 is inserted.

Specifically, reference is made to FIG. 6 and FIG. 8. The protruding part 22 protrudes through the heat dissipation window 110 and extends into the inside of the accommodation cavity 10, and the plug connector 300 includes an abutment surface 31 that abuts against the protruding part 22 when the plug connector 300 is inserted into the accommodation cavity 10. During the insertion process of the plug connector 300, the abutment surface 31 faces the inside of the accommodation cavity 10.

In this embodiment, the specific mating process of the plug connector 300 and the connection device includes the following steps. In the first step, the plug connector 300 is inserted through the insertion port, and the abutment surface 31 gradually approaches the protruding part 22 until it is aligned with the protruding part 22 toward the insertion port. In the second step, under the abutment effect between the abutment surface 31 and the protruding part 22, the heat dissipation block 200 moves synchronously with the plug connector 300 in the insertion direction of the plug connector 300, and based on the cooperation between the inclined guide surface 2311 and the guide matching part 40, in the step, the heat dissipation block 200 will gradually move closer to the accommodation cavity 10 of the housing 100. In the third step, the plug connector 300 is inserted in place, and the heat dissipation block 200 abuts against an upper surface of the plug connector 300 to form a thermally conductive connection.

Correspondingly, the process of pulling out the plug connector 300 from the inside of the connection device includes the following steps. In the first step, the plug connector 300 is pulled out from an inserted position, the heat is dissipated under the action of static friction between the plug connector 300 and the heat dissipation block 200, and the heat dissipation block 200 will move synchronously with the plug connector 300. Based on the cooperation between the inclined guide surface 2311 and the guide matching part 40, in this step, the heat dissipation block 200 will move away from the housing 100 until the heat dissipation block 200 is separated from the plug connector 300. In the second step, the plug connector 300 continues to be pulled out until it is completely disengaged from the connection device.

In certain embodiments of the present disclosure, the connection device further includes an elastic member, and an elastic force of the elastic member enables the heat dissipation block 200 to have a tendency to move away from the housing 100.

In a specific implementation, the elastic member can be a spring squeezed between the heat dissipation block 200 and the housing 100. Based on the setting of the spring, before the plug connector 300 is inserted in place, it can be ensured that the heat dissipation block 200 and the plug connector 300 have a gap there-between, thereby facilitating the insertion and extraction of the plug connector 300, and avoiding the sliding friction between the plug connector 300 and the heat dissipation block 200 during the insertion and removal process.

It should be understood that in other embodiments of the present disclosure, the elastic member may also be arranged in other forms. For example, it may also be an elastic piece, and the location of the elastic member is not limited to between the heat dissipation block 200 and the housing 100. For example, a spring forming the elastic member may also be disposed between the guide matching part 40 shown in FIG. 6 and an end of the guide hole 230 close to the housing 100. Other design methods will not be described herein.

In certain embodiments of the present disclosure, as shown in FIG. 4, FIG. 6, and FIG. 8, the heat dissipation block 200 further includes a heat conduction part 21 that cooperates with the heat dissipation window 110. On the mating surface of the top wall 11, the heat conduction part 21 is fixed on the mating surface and protrudes from the plane where the mating surface is located. In detail, the heat conduction part 21 is formed on the side of the heat dissipation block 200 close to the housing 100. After the plug connector 300 is inserted in place, the heat conduction part 21 is inserted into the heat dissipation window 110, and the heat dissipation block 200 is abutted by the heat conduction portion 21 and the plug connector 300 to form a heat conduction connection.

Reference is made to FIG. 4, FIG. 6 and FIG. 8. In this embodiment, the protruding part 22 protrudes toward the inside of the accommodating cavity 10 at the end of the heat conduction part 21 away from the insertion port. In an actual implementation of this embodiment, the heat conduction part 21 and the protruding part 22 are integrally formed. It should be understood that in other embodiments of the present disclosure, the heat conducting part 21 and the protruding part 22 may also be formed separately, and may be connected and fixed by connecting pieces such as screws.

In certain embodiments of the present disclosure, a flexible heat conduction pad (not shown in the figures) is provided on the side surface of the heat conduction part 21 facing the accommodating cavity 10. When the plug connector 300 is inserted in place, the setting of the flexible heat conduction pad can increase the contact tightness between the heat dissipation block 200 and the plug connector 300, thereby improving the heat dissipation efficiency. In addition, based on the flexible arrangement of the flexible heat conduction pad, the probability of damage due to contact with the plug connector 300 can be minimized.

In an embodiment of the present disclosure, the connection device further includes a locking module (not shown in the figures) that locks the position of the plug connector 300 relative to the housing 100 after the plug connector 300 is inserted in place. In practice, the locking module may include a groove and an elastic protrusion that cooperate with each other after the plug connector 300 is inserted in place. One of the groove and the elastic protrusion is disposed outside the plug connector 300, and the other is disposed inside the housing.

It should be understood that although this specification is described according to implementation modes, not every one of the implementation modes contains only one independent technical solution, and the way of description in the present disclosure is only for the sake of clarity, and those skilled in the art should take the specification as a whole, with each of the technical solutions in the embodiments being capable of being appropriately combined to form other embodiments that can be understood by those skilled in the art.

The series of detailed specifications listed above are only specific specifications of the feasible implementation modes of the present disclosure, and they are not intended to limit the protection scope of the present disclosure. Any equivalent implementation mode or all changes should be included within the scope of protection of the present disclosure.

1. A connection device, comprising a housing and a heat dissipation block, wherein the housing is provided with an accommodation cavity for insertion of a plug connector and with a heat dissipation window in communication with the accommodation cavity, the heat dissipation block is disposed on a side of the housing provided with the heat dissipation window, wherein the connection device further comprises an adjustment assembly for adjusting the heat dissipation block so as to make the heat dissipation block close to or distant from the accommodation cavity; and the heat dissipation block comprises a thermally conductive connection state in which the heat dissipation block approaches to abut against the plug connector after the plug connector is inserted in place.

2. The connection device according to claim 1, wherein the adjustment assembly comprises an inclined guide surface and a guide matching part, the inclined guide surface is located on the heat dissipation block and is disposed away from the housing, the inclined guide surface is inclined toward the housing in an insertion direction of the plug connector, and the guide matching part is fixedly arranged relative to the housing and is slidingly fitted with the inclined guide surface.

3. The connection device according to claim 2, wherein an angle between a plane where the inclined guide surface is located and the insertion direction of the plug connector is 20-45°.

4. The connection device according to claim 2, wherein the heat dissipation block comprises a guide hole, and a part of a hole wall of the guide hole facing away from the housing forms the inclined guide surface; the connection device comprises a fixed rod fixedly arranged relative to the housing and matched to an inside of the guide hole, and a part of the fixed rod fitted in the guide hole forms the guide matching part.

5. The connection device according to claim 4, wherein the heat dissipation block comprises a plurality of fins extending in a same direction as the insertion direction of the plug connector, and the guide hole is located on an outermost fin of the fins.

6. The connection device according to claim 2, wherein the adjustment assembly further comprises a horizontal guide surface extending in a same direction as the insertion direction of the plug connector, and the horizontal guide surface is connected to an end of the inclined guide surface away from the accommodation cavity.

7. The connection device according to claim 1, wherein the adjustment assembly comprises an inclined guide surface and a guide matching part, the inclined guide surface is located on the housing and is disposed away from the heat dissipation block, the inclined guide surface is inclined toward the heat dissipation block in a direction opposite to an insertion direction of the plug connector, and the guide matching part is fixedly arranged relative to the heat dissipation block and is slidingly fitted with the inclined guide surface.

8. The connection device according to claim 7, wherein an angle between a plane where the inclined guide surface is located and the insertion direction of the plug connector is 20-45°.

9. The connection device according to claim 7, wherein the housing comprises a guide hole, and a part of a hole wall of the guide hole facing away from the heat dissipation block forms the inclined guide surface; the connection device comprises a fixed rod fixedly arranged relative to the heat dissipation block and matched to an inside of the guide hole, and a part of the fixed rod fitted in the guide hole forms the guide matching part.

10. The connection device according to claim 7, wherein the adjustment assembly further comprises a horizontal guide surface extending in a same direction as the insertion direction of the plug connector, and the horizontal guide surface is connected to an end of the inclined guide surface away from the heat dissipation block.

11. The connection device according to claim 1, wherein the adjustment assembly further comprises a protruding part fixed to the heat dissipation block, and the protruding part protrudes into an inside of the accommodation cavity for abutting against the plug connector to push the heat dissipation block when the plug connector is inserted.

12. The connection device according to claim 1, wherein the connection device further comprises an elastic member, and an elastic force of the elastic member enables the heat dissipation block to have a tendency to move away from the housing.

13. The connection device according to claim 1, wherein the plug connector is an optical module.

14. The connection device according to claim 1, wherein an insertion direction of the plug connector is parallel to a plane where the heat dissipation window is located.
